(19) United States
(12) Patent Application Publication
(10) Pub. No.: US 2026/0292985 A1
(43) Pub. Date: Sep. 24, 2026

(54) PRINTED CIRCUIT BOARD

(71) Applicant: SAMSUNG ELECTRO-MECHANICS CO., LTD., Suwon-si (KR)

(72) Inventors: Young Kuk Ko, Suwon-si (KR); Sanghoon Kim, Suwon-si (KR); Gyumook Kim, Suwon-si (KR); Taehun Kim, Suwon-si (KR)

(73) Assignee: SAMSUNG ELECTRO-MECHANICS CO., LTD., Suwon-si (KR)

(21) Appl. No.: 19/307,969

(22) Filed: Aug. 22, 2025

(30) Foreign Application Priority Data
Mar. 20, 2025 (KR) 10-2025-0036159

(51) Int. Cl. H05K 1/11; H05K 1/02

(52) U.S. Cl. CPC H05K 1/116; H05K 1/0296; H05K 2201/09036; H05K 2201/096; H05K 2201/2081

(57) ABSTRACT

A printed circuit board according to an embodiment may comprise an insulating layer, a wiring layer embedded in the insulating layer, a solder resist layer positioned on the insulating layer, a cavity penetrating the solder resist layer and a portion of the insulating layer, and a blocking pattern positioned on the insulating layer, surrounding an edge of the cavity, and covered by the solder resist layer.

### CROSS-REFERENCE TO RELATED APPLICATION

This application claims priority to and the benefit of Korean Patent Application No. 10-2025-0036159 filed with the Korean Intellectual Property Office on Mar. 20, 2025, the entire contents of which are incorporated herein by reference.

### BACKGROUND

### (a) Field

The present disclosure relates to a printed circuit board.

### 2. Description of the Related Art

A printed circuit board is a circuit pattern formed with a conductive material such as copper on an insulating material. As electronic devices in the IT field such as mobile phones become smaller, a method of forming a cavity in the printed circuit board and mounting electronic components such as ICs, active components, or passive components inside the cavity has been proposed.

When forming the cavity in the printed circuit board, an undercut or protrusion may be formed on the lower sidewall of the cavity. Moreover, when forming a solder resist layer on the surface of the printed circuit board having the cavity, a material for forming the solder resist may move into the cavity, causing solder resist to be formed in an unnecessary portion, or the thickness of the solder resist layer at the edge of the cavity may be formed thinly.

### SUMMARY

The embodiments provide a printed circuit board having a solder resist layer of uniform thickness around the cavity to prevent undercuts or protrusions on the lower sidewall of the cavity.

However, the problems that the embodiments seek to solve are not limited to the problems described above and may be expanded in various ways within the scope of the technical ideas included in the embodiments.

A printed circuit board according to an embodiment may comprise an insulating layer, a wiring layer embedded in the insulating layer, a solder resist layer positioned on the insulating layer, a cavity penetrating the solder resist layer and a portion of the insulating layer, and a blocking pattern positioned on the insulating layer, surrounding an edge of the cavity, and covered by the solder resist layer.

The printed circuit board may further comprise a pad layer positioned on the insulating layer. The solder resist layer may have an opening that exposes the pad layer. A thickness of the blocking pattern may be different from a thickness of the pad layer.

The blocking pattern and the pad layer may be positioned on the same layer and include the same material.

The thickness of the blocking pattern may be greater than the thickness of the pad layer.

The thickness of the blocking pattern may be substantially the same as the thickness of the pad layer.

The insulating layer may include a first insulating layer and a second insulating layer positioned on the first insulating layer, the wiring layer may include a first wiring layer embedded in the first insulating layer and a second wiring layer embedded in the second insulating layer, and the cavity may penetrate the second insulating layer and exposes the first insulating layer.

The printed circuit board may further comprise a dummy pattern positioned on the first insulating layer and surrounding a bottom surface of the cavity along a sidewall of the cavity.

A first portion of the dummy pattern may be positioned below the sidewall of the cavity.

A second portion of the dummy pattern may be exposed by the cavity.

The printed circuit board may further comprise a connecting portion positioned in the cavity and positioned on the first insulating layer. The dummy pattern and the connecting portion may be positioned on the same layer and may include the same material as each other.

A thickness of the dummy pattern may be substantially the same as a thickness of the connecting portion.

The second insulating layer may include a photosensitive insulating layer.

According to the embodiments, a printed circuit board having a solder resist layer of uniform thickness around the cavity to prevent undercuts or protrusions on the lower sidewall of the cavity may be provided.

However, it is obvious that the effects of the embodiments are not limited to the above-described effects, and may be variously extended without departing from the concept and scope of the present disclosure.

### BRIEF DESCRIPTION OF THE DRAWINGS

FIG. 1 is a plan view of a printed circuit board according to an embodiment.

FIG. 2 is a cross-sectional view taken along line I-I′ of FIG. 1.

FIGS. 3, 4, 5, 6, 7, 8 and 9 are cross-sectional views illustrating a method for manufacturing a printed circuit board according to various embodiments.

FIG. 10 is a plan view of a printed circuit board according to another embodiment.

FIG. 11 is a cross-sectional view taken along line I-I′ of FIG. 10.

FIG. 12 is a cross-sectional view illustrating a method for manufacturing a printed circuit board according to another embodiment.

FIG. 13 is a cross-sectional view of a printed circuit board according to another embodiment.

FIG. 14 is a cross-sectional view of a printed circuit board according to another embodiment.

### DETAILED DESCRIPTION

Hereinafter, various embodiments of the present disclosure will be described in detail so that a person of ordinary skill in the technical field to which the present disclosure belongs can easily implement it with reference to the accompanying drawings. The present disclosure may be implemented in various different forms and is not limited to the embodiments described herein.

In order to clearly describe the present disclosure, parts unrelated to the description are omitted in the drawings, and the same reference numerals are designated to the same or similar elements throughout the specification.

The accompanying drawings are provided only in order to allow embodiments disclosed in the present specification to be easily understood and are not to be interpreted as limiting the technical concept disclosed in the present specification, and it is to be understood that the present disclosure includes all modifications, equivalents, and substitutions without departing from the scope and concept of the present disclosure.

In addition, the size and thickness of each element illustrated in the drawings are arbitrarily illustrated for convenience of explanation, so this disclosure is not necessarily limited to the drawings. In the drawings, thicknesses are enlarged to clearly illustrate layers and regions. Further, in the drawings, for convenience of explanation, the thickness of some layers and areas are exaggerated.

Furthermore, it will be understood that when an element such as a layer, film, region, or substrate is referred to as being “on” another element, it can be directly on the other element or intervening elements may also be present. On the contrary, when an element is referred to as being “directly on” another element, there are no intervening elements present. Furthermore, in the specification, the word “on” or “above” means positioned on or below the object portion and does not necessarily mean positioned on the upper side of the object portion based on a gravitational direction.

Furthermore, throughout the specification, unless explicitly described to the contrary, the word “comprise” and variations such as “comprises” or “comprising” will be understood to imply the inclusion of other elements but not the exclusion of any other elements.

Throughout the specification, the term “in a plane view” refers to viewing the target portion from above, while the term “in a cross-sectional view” refers to viewing the target portion from the side after making a vertical section.

Furthermore, throughout the specification, “connected” means that two or more elements are not only directly connected, but two or more elements may be connected indirectly through other elements, physically connected as well as being electrically connected, or it may be referred to by different names depending on the location or function but may mean integral.

Hereinafter, various embodiments and modified embodiments will be described in detail with reference to the drawings.

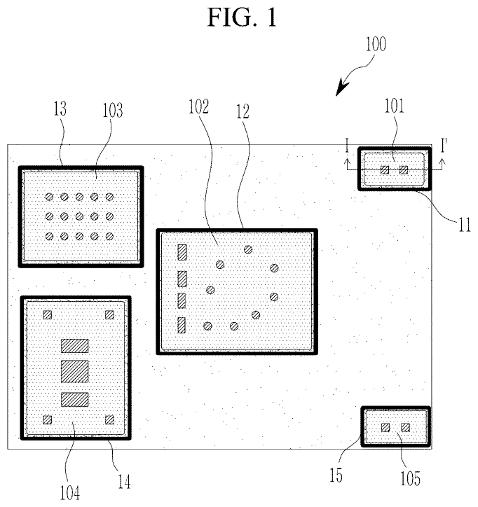

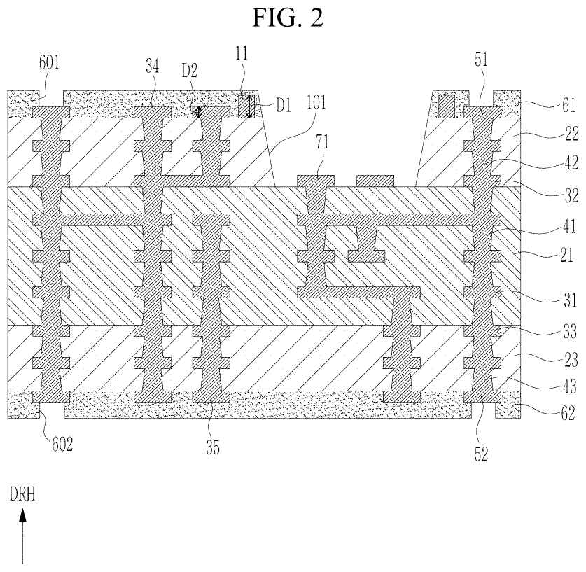

Referring to FIGS. 1 and 2, a printed circuit board according to an embodiment is described. FIG. 1 is a plan view of a printed circuit board according to an embodiment, and FIG. 2 is a cross-sectional view taken along line I-I′ of FIG. 1.

Referring to FIG. 1, a printed circuit board 100 according to an embodiment may include a plurality of cavities 101, 102, 103, 104, and 105.

Electronic components or semiconductor elements may be mounted in the plurality of cavities 101, 102, 103, 104, and 105.

The printed circuit board 100 may include a blocking pattern 11, 12, 13, 14, and 15 surrounding the edges of a plurality of cavities 101, 102, 103, 104, and 105.

The blocking patterns, 11, 12, 13, 14, and 15 may be covered by a solder resist layer as described later.

Referring to FIG. 2 together with FIG. 1, the printed circuit board 100 according to the present embodiment may include a plurality of insulating layers 21, 22, 23, a plurality of wiring layers 31, 32, 33 embedded in the plurality of insulating layers 21, 22, 23, a plurality of vias 41, 42, 43 connecting some of the plurality of wiring layers 31, 32, 33 to each other, a plurality of pad layers 51, 52, a solder resist layer 61, 62, a cavity 101, and a blocking pattern 11 positioned over the plurality of insulating layers 21, 22, 23 and surrounding an edge of the cavity 101. FIG. 2 illustrates only one cavity 101 among the plurality of cavities 101, 102, 103, 104, and 105 of FIG. 1, but many of the features of cavity 101 are applicable to all of the other cavities 102, 103, 104, and 105.

The plurality of insulating layers 21, 22, 23 may include a first insulating layer 21, a second insulating layer 22 positioned on the first insulating layer 21 along the height direction DRH, and a third insulating layer 23 positioned under the first insulating layer 21 along the height direction DRH. At least one of the first insulating layer 21, the second insulating layer 22, and the third insulating layer 23 may be an insulating layer in which the plurality of insulating layers are laminated.

The first insulating layer 21 may include a resin, and may include a thermosetting resin such as an epoxy resin or a thermoplastic resin such as polyimide PI. The first insulating layer 21 may include prepreg PPG or a build-up film, but the embodiment is not limited thereto.

The second insulating layer 22 may include a photosensitive material, and the second insulating layer 22 may include a PID (Photo Imageable Dielectric).

The third insulating layer 23 may include a photosensitive material, and the third insulating layer 23 may include a PID.

The plurality of wiring layers 31, 32, 33 may include a plurality of first wiring layers 31 embedded in the first insulating layer 21, a plurality of second wiring layers 32 embedded in the second insulating layer 22, and a plurality of third wiring layers 33 embedded in the third insulating layer 23.

The plurality of vias 41, 42, 43 may include a plurality of first vias 41 located within the first insulating layer 21, a plurality of second vias 42 located within the second insulating layer 22, and a plurality of third vias 43 located within the third insulating layer 23.

At least some of the plurality of first wiring layers 31 may be connected to each other through a plurality of first vias 41, at least some of the plurality of second wiring layers 32 may be connected to each other through a plurality of second vias 42, and at least some of the plurality of third wiring layers 33 may be connected to each other through a plurality of third vias 43.

A plurality of first pad layers 51 and a plurality of fourth wiring layers 34 may be positioned on the second insulating layer 22 and may be connected to the plurality of second wiring layers 32 through some of the plurality of second vias 42.

A plurality of second pad layers 52 and a plurality of fifth wiring layers 35 may be positioned under the third insulating layer 23 and may be connected to a plurality of third wiring layers 33 through some of the plurality of third vias 43.

The plurality of wiring layers 31, 32, 33, 35, the plurality of vias 41, 42, 43, and the pad layers 51, 52 may include copper (Cu). The plurality of wiring layers 31, 32, 33, 35, the plurality of vias 41, 42, 43, and the pad layers 51, 52 may include a conductive material such as gold (Au), silver (Ag), tungsten (W), aluminum (Al), nickel (Ni), or palladium (Pd). However, the embodiment is not limited thereto, and the conductive material may vary.

The solder resist layer 61, 62 may include a first solder resist layer 61 positioned on a plurality of first pad layers 51 and a plurality of fourth wiring layers 34, and a second solder resist layer 62 positioned under a plurality of second pad layers 52 and a plurality of fifth wiring layers 35.

The first solder resist layer 61 may have a first opening 601 exposing a plurality of first pad layers 51, and the second solder resist layer 62 may have a second opening 602 exposing a plurality of second pad layers 52.

The cavity 101 may be formed to penetrate the second insulating layer 22 and the first solder resist layer 61.

A plurality of connection portions 71 may be positioned within the cavity 101, and electronic components or semiconductor elements mounted within the cavity 101 may be electrically connected to a printed circuit board 100 through the plurality of connection portions 71.

The plurality of connecting portions 71 may be positioned on the first insulating layer 21 and may be formed of the same layer as the lowest layer among the plurality of second wiring layers 32 embedded in the second insulating layer 22, but the embodiment is not limited thereto.

The connecting portions 71 may include copper (Cu). The connecting portions 71 may include a conductive material such as gold (Au), silver (Ag), tungsten (W), aluminum (Al), nickel (Ni), or palladium (Pd). However, the embodiment is not limited thereto, and the conductive material may vary.

A blocking pattern 11 may be positioned on the second insulating layer 22. The blocking pattern 11 may be covered by the first solder resist layer 61.

The blocking pattern 11 may have a planer shape surrounding the cavity 101. The blocking pattern 11 may prevent the material for forming the first solder resist layer 61 from moving into the cavity 101 when the first solder resist layer is formed.

The blocking pattern 11 is positioned on the same layer as the plurality of first pad layers 51 and the plurality of fourth wiring layers 34, and may include the same material as the plurality of first pad layers 51 and the plurality of fourth wiring layers 34.

When forming the solder resist layer, the material including an epoxy resin and a hardener for forming the solder resist layer may be laminated on the second insulating layer 22 and then hardened through heat treatment or the like to form the solder resist layer. At this time, the material layer for forming the solder resist layer laminated around the cavity may move into the cavity due to the height difference of the cavity, and as a result, the solder resist layer may not be formed around the cavity or may be formed with a thinner thickness than other parts. In this case, the area around the cavity may not be protected by the solder resist, and corrosion, etc. may occur around the cavity.

According to an embodiment, the printed circuit board 100 may include a blocking pattern 11 positioned on a second insulating layer 22 and having a planar shape surrounding a cavity 101. When the solder resist layer is formed, the material layer for forming the solder resist layer may be prevented from moving into the cavity, and thereby the solder resist layer may be formed to have a uniform thickness even around the cavity. Therefore, corrosion, etc. may be prevented from occurring around the cavity.

Referring to FIG. 2, a first thickness D1 of the blocking pattern 11 may be greater than a second thickness D2 of the plurality of first pad layers 51 and the plurality of fourth wiring layers 34.

When the first thickness D1 of the blocking pattern 11 is greater than the second thickness D2 of the plurality of first pad layers 51 and the plurality of fourth wiring layers 34, when the solder resist layer is formed, the material layer for forming the solder resist layer may be more effectively prevented from moving into the cavity.

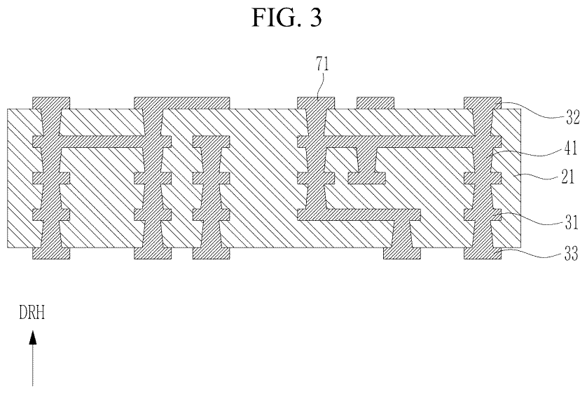

Referring to FIGS. 3 to 9 together with FIG. 2, a method for manufacturing a printed circuit board according to an embodiment is briefly described. FIGS. 3 to 9 are cross-sectional views illustrating a method for manufacturing a printed circuit board according to an embodiment.

Referring to FIG. 3, the first insulating layer 21, the plurality of first wiring layers 31 embedded in the first insulating layer 21, the plurality of first vias 41 positioned within the first insulating layer 21 and connecting some of the plurality of first wiring layers 31, the plurality of second wiring layers 32 and the plurality of connecting portions 71 positioned over the first insulating layer 21, and the plurality of third wiring layers 33 positioned under the first insulating layer 21 may be formed.

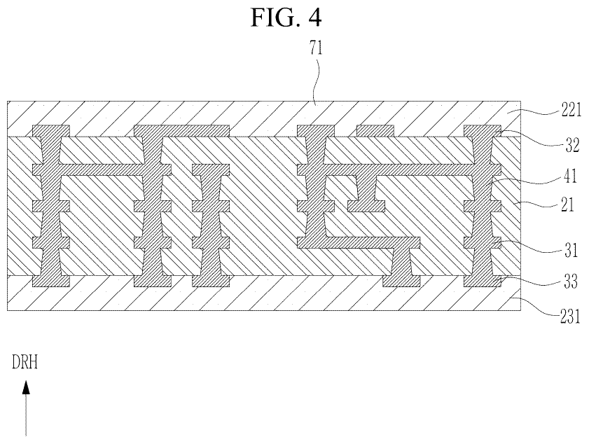

Referring to FIG. 4, a first sub-insulating layer 221 covering the plurality of second wiring layers 32 may be laminated on the first insulating layer 21, and a second sub-insulating layer 231 covering the plurality of third wiring layers 33 may be laminated under the first insulating layer 21.

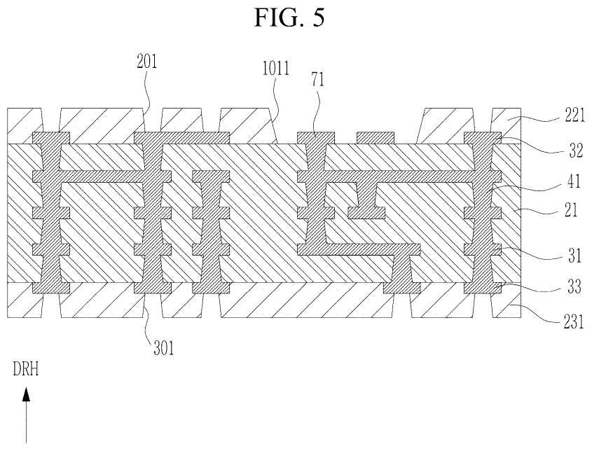

Referring to FIG. 5, a plurality of first holes 201 exposing at least a portion of a plurality of second wiring layers 32 and a plurality of auxiliary cavities 1011 exposing a plurality of connection portions 71 may be formed in the first sub-insulating layer 221, and a plurality of second holes 301 exposing at least a portion of a plurality of third wiring layers 33 may be formed in a second sub-insulating layer 231. The spare cavity 1011 may be a part of the cavity 101.

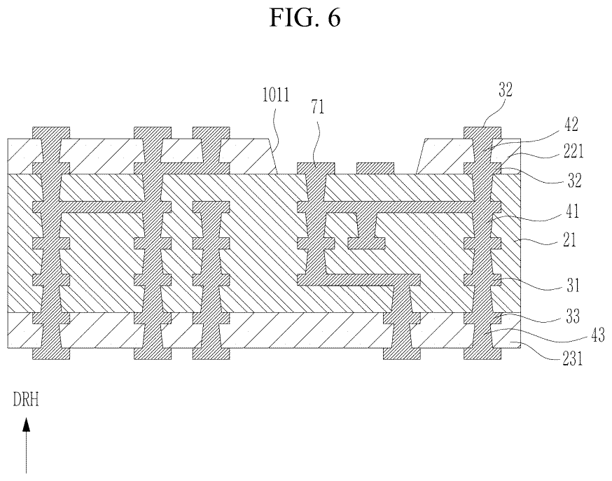

Referring to FIG. 6, the plurality of second vias 42 may be formed in the plurality of first holes 201 of the first sub-insulating layer 221, the plurality of second wiring layers 32 may be formed on the first sub-insulating layer 221, the plurality of third vias 43 may be formed in the plurality of second holes 301 of the second sub-insulating layer 231, and the plurality of third wiring layers 33 may be formed under the second sub-insulating layer 231.

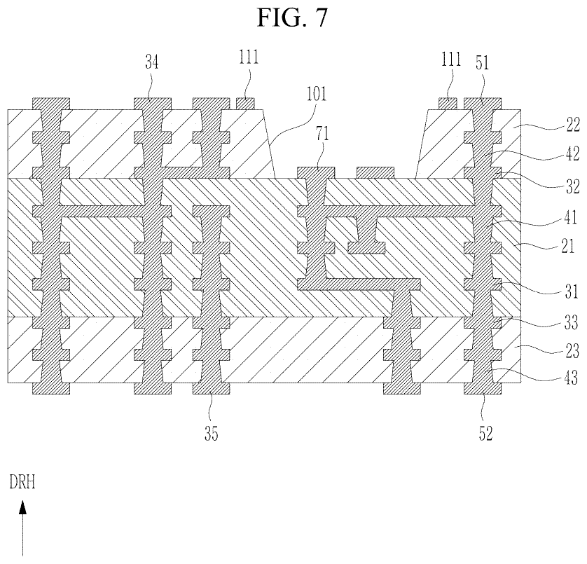

By repeatedly stacking the first sub-insulating layer 221 and the second sub-insulating layer 231, and forming the plurality of second vias 42, the plurality of second wiring layers 32, the plurality of third vias 43, and the plurality of third wiring layers 33, as shown in FIG. 7, the second insulating layer 22, the cavity 101 formed in the second insulating layer 22 and exposing the plurality of connection portions 71, the plurality of second wiring layers 32 embedded in the second insulating layer 22, the plurality of second vias 42 positioned in the second insulating layer 22 and connecting some of the plurality of second wiring layers 32, and the plurality of fourth wiring layers 34 positioned on the second insulating layer 22, a preliminary blocking pattern 111, and the plurality of first pad layers 51, the third insulating layer 23, the plurality of third wiring layers 33 embedded in the third insulating layer 23, and the plurality of third vias 43 positioned within the insulating layer 23 and connecting some of the plurality of third wiring layers 33, the plurality of fifth wiring layers 35 positioned under the third insulating layer 23, and the plurality of second pad layers 52 may be formed.

The plurality of fourth wiring layers 34, the preliminary blocking pattern 111 and the plurality of first pad layers 51 may be formed together and positioned on the second insulating layer 22 and may include the same material.

A thickness of the preliminary blocking pattern 111 may be substantially equal to the thickness of the plurality of fourth wiring layers 34 and the plurality of first pad layers 51.

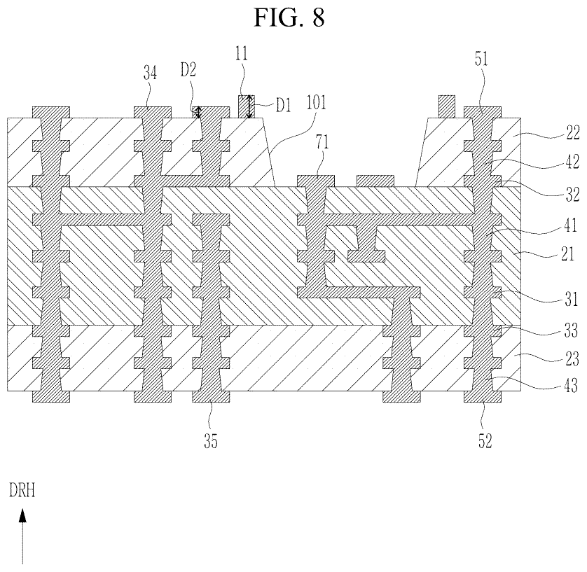

Referring to FIG. 8, the blocking pattern 11 may be formed by additionally forming a conductive layer only on the preliminary blocking pattern 111 through a method such as plating. Through this, the blocking pattern 11 having the first thickness D1 greater than the second thickness D2 of a plurality of first pad layers 51 and a plurality of fourth wiring layers 34 may be formed.

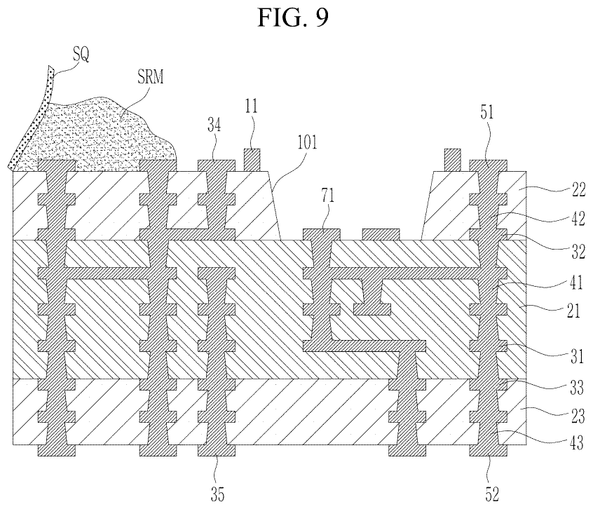

Referring to FIG. 9, a solder resist material layer SRM may be applied on the second insulating layer 22 in which a cavity 101 is formed. In FIG. 9, the solder resist material layer SRM is illustrated as being applied on the second insulating layer 22 using a squeegee SQ, but the embodiment is not limited thereto, and the solder resist material layer SRM may be applied through a spin process or an inkjet process, etc.

When applying the solder resist material layer SRM on the second insulating layer 22, the blocking pattern 11 having the planar shape surrounding the cavity 101 may act like a dam, thereby preventing the solder resist material layer SRM applied around the cavity 101 from moving into the cavity 101 and flowing in.

As described above, the first thickness D1 of the blocking pattern 11 may be greater than the second thickness D2 of the plurality of first pad layers 51 and the plurality of fourth wiring layers 34, and in this case, the solder resist material layer SRM may be more effectively prevented from moving into and flowing into the cavity 101.

In addition, since at least a portion of the blocking pattern 11 may be formed together with a plurality of first pad layers 51 and a plurality of fourth wiring layers 34 and formed through an additional plating process, the manufacturing process may be prevented from becoming complicated when forming the blocking pattern 11.

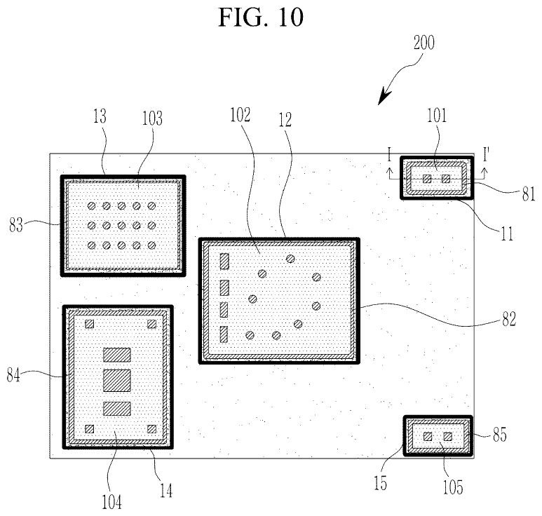

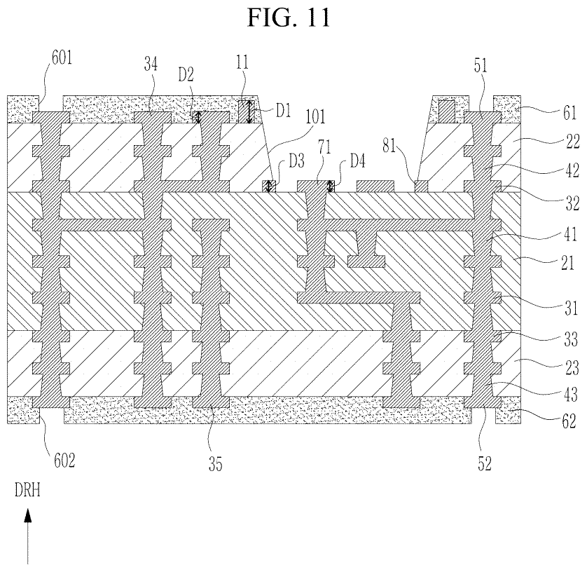

Referring to FIGS. 10 and 11, a printed circuit board 200 according to another embodiment will be described. FIG. 10 is a plan view of a printed circuit board according to another embodiment, and FIG. 11 is a cross-sectional view taken along line I-I′ of FIG. 10.

Referring to FIGS. 10 and 11, the printed circuit board 200 according to the present embodiment is similar to the printed circuit board 100 according to the previously described embodiment. A detailed description of the same component is omitted

Referring to FIG. 10 together with FIG. 1, the printed circuit board 200 according to the present embodiment may include a plurality of cavities 101, 102, 103, 104, and 105 and a blocking pattern 11, 12, 13, 14, and 15 surrounding the edges of the plurality of cavities 101, 102, 103, 104, and 105.

Unlike the printed circuit board 100 according to the embodiment illustrated in FIGS. 1 and 2, the printed circuit board 200 according to the present embodiment may further include dummy patterns 81, 82, 83, 84, and 85 positioned along the edges of the plurality of cavities 101, 102, 103, 104, and 105.

Referring to FIGS. 10 and 11 together with FIGS. 1 and 2, the printed circuit board 200 may include the plurality of insulating layers 21, 22, 23, the plurality of wiring layers 31, 32, 33 embedded in the plurality of insulating layers 21, 22, 23, the plurality of vias 41, 42, 43 connecting some of the plurality of wiring layers 31, 32, 33 to each other, the plurality of pad layers 51, 52, the solder resist layer 61, 62, the cavity 101, the blocking pattern 11 positioned over the plurality of insulating layers 21, 22, 23 and surrounding an edge of the cavity 101, and the dummy pattern 81 positioned between the first insulating layer 21 and the second insulating layer 22.

FIG. 11 illustrates only one cavity 101 of the plurality of cavities 101, 102, 103, 104, and 105 of FIG. 10, but many of the features of cavity 101 are applicable to all of the other cavities 102, 103, 104, and 105.

Along the height direction DRH, the dummy pattern 81 may be positioned on the first insulating layer 21. A portion of the dummy pattern 81 may be covered by the second insulating layer 22, and the remaining portion of the dummy pattern 81 may be exposed by the cavity 101.

The dummy pattern 81 may surround the bottom surface of the cavity 101 along the side wall of the cavity 101.

The dummy pattern 81 may be positioned on the same layer as the plurality of connecting portions 71 located within the cavity 101 and may contain the same material.

A third thickness D3 of the dummy pattern 81 may be substantially equal to a fourth thickness D4 of the connecting portion 71 located within the cavity 101. However, the embodiment is not limited thereto.

The dummy pattern 81 serves to set the area formed by the side wall of the cavity 101 when forming the cavity 101, thereby preventing the second insulating layer 22 from being over-etched or having a portion remaining without being partially etched in the lower area of the side wall of the cavity 101 while forming the cavity 101.

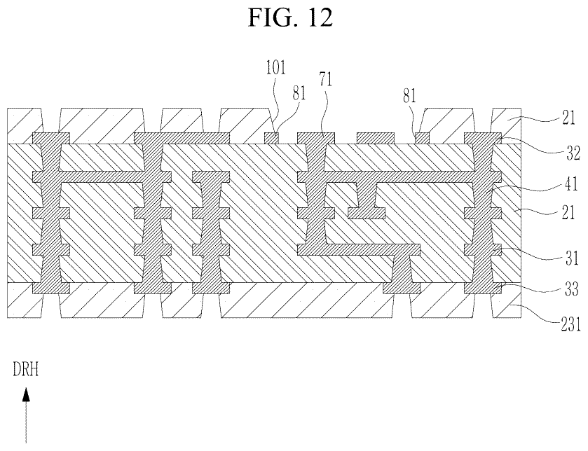

As shown in FIG. 12, when the cavity 101 is formed by exposing the second insulating layer 22, if a sufficient amount of light does not reach the edge of the cavity 101 or if an unnecessarily strong amount of light reaches it, a protrusion or undercut may occur at the lower part of the side wall of the cavity 101.

According to the embodiment, the printed circuit board 200 may include a dummy pattern 81 positioned at the lower portion of the sidewall of the cavity 101 so as to surround the bottom surface of the cavity 101 along the sidewall of the cavity 101, so that the lower region of the cavity 101 may be defined by the dummy pattern 81 before forming the cavity 101.

According to the embodiment, the printed circuit board 200 may include a dummy pattern 81, the insulating layer 22 is prevented from not being removed and remaining partially inside the cavity 101 thtough sufficient light may be exposed to the edge of the cavity 101. Even if an unnecessary amount of light reaches the edge of the cavity 101, the unnecessary amount of light may be applied to the dummy pattern 81, thereby preventing the insulating layer 22 from being over-etched.

In addition, according to the embodiment, the printed circuit board 200 includes the blocking pattern 11 positioned on the second insulating layer 22 and having a planar shape surrounding the cavity 101, so that when the solder resist layer is formed, the material layer for forming the solder resist layer may be prevented from moving into the cavity, and thereby the solder resist layer may be formed to have a uniform thickness even around the cavity. Therefore, corrosion, etc. may be prevented from occurring around the cavity.

The first thickness D1 of the blocking pattern 11 may be greater than the second thickness D2 of the plurality of first pad layers 51 and the plurality of fourth wiring layers 34.

The first thickness D1 of the blocking pattern 11 is greater than the second thickness D2 of the plurality of first pad layers 51 and the plurality of fourth wiring layers 34, and therefore the material layer for forming the solder resist layer may be more effectively prevented from moving into the cavity when the solder resist layer is formed.

In addition, since at least a portion of the blocking pattern 11 may be formed simultaneously with the plurality of first pad layers 51 and the plurality of fourth wiring layers 34 and formed through an additional plating process, the manufacturing process may be prevented from becoming complicated when forming the blocking pattern 11.

Many of the features of the printed circuit board 100 according to the embodiment described above are all applicable to the printed circuit board 200 according to the present embodiment.

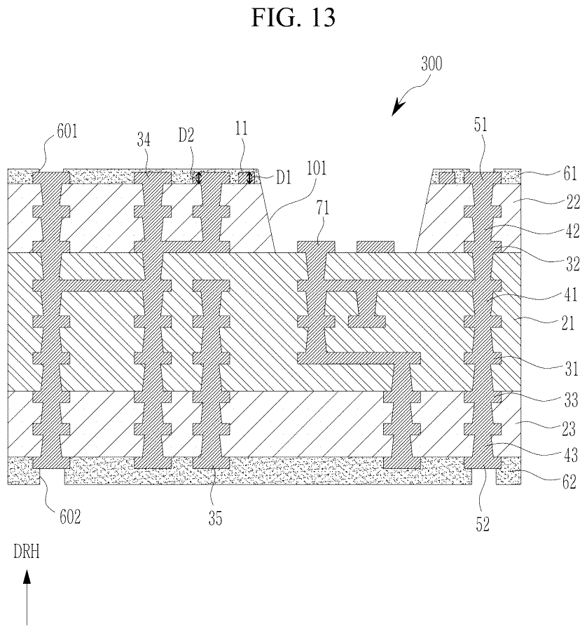

Referring to FIG. 13, a printed circuit board 300 according to another embodiment will be described. FIG. 13 is a cross-sectional view of a printed circuit board according to another embodiment.

Referring to FIG. 13, the printed circuit board 300 according to the present embodiment is similar to the printed circuit board 100 according to the embodiment described above. A detailed description of the same component is omitted.

Referring to FIG. 13, the printed circuit board 300 according to the present embodiment may include the plurality of insulating layers 21, 22, 23, the plurality of wiring layers 31, 32, 33 embedded in the plurality of insulating layers 21, 22, 23, the plurality of vias 41, 42, 43 connecting some of the plurality of wiring layers 31, 32, 33 to each other, the plurality of pad layers 51, 52, the solder resist layer 61, 62, the cavity 101, and the blocking pattern 11 positioned over the plurality of insulating layers 21, 22, 23 and surrounding an edge of the cavity 101.

The blocking pattern 11 may be positioned on the second insulating layer 22 in which the cavity 101 is formed, and the blocking pattern 11 may be covered by the first solder resist layer 61.

The blocking pattern 11 may have a planar shape surrounding the cavity 101. The blocking pattern 11 may prevent the material for forming the first solder resist layer 61 from moving into the cavity 101 when the first solder resist layer is formed.

The plurality of first pad layers 51 and the plurality of fourth wiring layers 34, and the blocking pattern 11 may be positioned on the same layer and may include the same material.

Unlike the printed circuit board 100 according to the previously described embodiments, according to the present embodiment, the first thickness D1 of the blocking pattern 11 may be substantially equal to the second thickness D2 of the plurality of first pad layers 51 and the plurality of fourth wiring layers 34, but the embodiment is not limited thereto.

Since the blocking pattern 11 may be formed simultaneously with the plurality of first pad layers 51 and the plurality of fourth wiring layers 34, it is possible to prevent the manufacturing process from becoming complicated, the manufacturing time from increasing, or the manufacturing cost from increasing when the blocking pattern 11 is formed.

Many of the features of the printed circuit boards 100, 200 according to the embodiments described above are all applicable to the printed circuit board 300 according to the present embodiment.

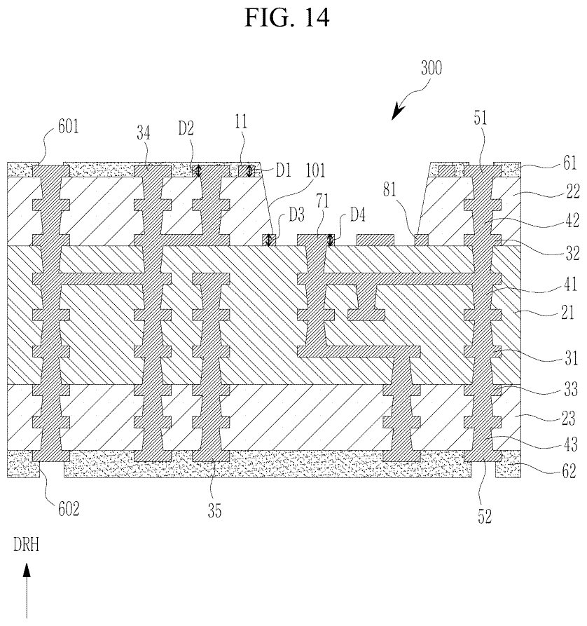

Referring to FIG. 14, a printed circuit board 400 according to another embodiment is described. FIG. 14 is a cross-sectional view of a printed circuit board according to another embodiment.

Referring to FIG. 14, the printed circuit board 400 according to the present embodiment is similar to the printed circuit board 200 according to the previously described embodiment. A detailed description of the same component is omitted.

Referring to FIG. 14, a printed circuit board 400 may include the plurality of insulating layers 21, 22, 23, the plurality of wiring layers 31, 32, 33 embedded in the plurality of insulating layers 21, 22, 23, the plurality of vias 41, 42, 43 connecting some of the plurality of wiring layers 31, 32, 33 to each other, the plurality of pad layers 51, 52, the solder resist layer 61, 62, the cavity 101, the blocking pattern 11 positioned over the plurality of insulating layers 21, 22, 23 and surrounding an edge of the cavity 101, and the dummy pattern 81 positioned over the first insulating layer 21 and below a sidewall of the cavity 101.

The blocking pattern 11 may be positioned on the second insulating layer 22 in which the cavity 101 is formed, and the blocking pattern 11 may be covered by the first solder resist layer 61.

The blocking pattern 11 may have a planar shape surrounding the cavity 101. The blocking pattern 11 may prevent the material for forming the first solder resist layer 61 from moving into the cavity 101 when the first solder resist layer is formed.

The plurality of first pad layers 51 and the plurality of fourth wiring layers 34, and the blocking pattern 11 may be positioned on a same layer, and the blocking pattern 11 may include the same material as the plurality of first pad layers 51 and the plurality of fourth wiring layers 34. The first thickness D1 of the blocking pattern 11 may be substantially equal to the second thickness D2 of the plurality of first pad layers 51 and the plurality of fourth wiring layers 34, but the embodiment is not limited thereto.

Since the blocking pattern 11 may be formed simultaneously with the plurality of first pad layers 51 and the plurality of fourth wiring layers 34, it is possible to prevent the manufacturing process from becoming complicated, the manufacturing time from increasing, or the manufacturing cost from increasing.

Along the height direction DRH, the dummy pattern 81 may be positioned on the first insulating layer 21. A portion of the dummy pattern 81 may be covered by the second insulating layer 22, and the remaining portion of the dummy pattern 81 may be exposed by the cavity 101. That is, a portion of the dummy pattern 81 may be covered by the side wall of the cavity 101.

The dummy pattern 81 may be positioned on the same layer as the plurality of connecting portions 71 located within the cavity 101, and the dummy pattern 81 may include the same material as the plurality of connecting portions 71.

The third thickness D3 of the dummy pattern 81 may be substantially equal to the fourth thickness D4 of the connecting portion 71 located within the cavity 101. However, the embodiment is not limited thereto.

The dummy pattern 81 serves to set the area formed by the side wall of the cavity 101 when forming the cavity 101, thereby preventing the second insulating layer 22 from being over-etched or having a portion remaining without being partially etched in the lower area of the side wall of the cavity 101.

Many of the features of the printed circuit boards 100, 200, 300 according to the embodiments described above are all applicable to the printed circuit board 400 according to the present embodiment.

Although the preferred embodiments have been described above, the inventive concept is not limited thereto, and various modifications may be made within the scope of the claims, the detailed description of the embodiments, and the attached drawings, which also fall within the scope of this disclosure.

What is claimed is:

1. A printed circuit board, comprising:
an insulating layer;
a wiring layer embedded in the insulating layer;
a solder resist layer positioned on the insulating layer;
a cavity penetrating the solder resist layer and a portion of the insulating layer; and
a blocking pattern positioned on the insulating layer, surrounding an edge of the cavity, and covered by the solder resist layer.

2. The printed circuit board of claim 1, further comprising:
a pad layer positioned on the insulating layer,
wherein the solder resist layer has an opening that exposes the pad layer, and
wherein a thickness of the blocking pattern is different from a thickness of the pad layer.

3. The printed circuit board of claim 2,
wherein the blocking pattern and the pad layer are positioned on the same layer and include the same material.

4. The printed circuit board of claim 3,
wherein the thickness of the blocking pattern is greater than the thickness of the pad layer.

5. The printed circuit board of claim 2,
wherein the insulating layer includes a first insulating layer and a second insulating layer positioned on the first insulating layer,
wherein the wiring layer includes a first wiring layer embedded in the first insulating layer and a second wiring layer embedded in the second insulating layer, and
wherein the cavity penetrates the second insulating layer and exposes a portion of the first insulating layer.

6. The printed circuit board of claim 5, further comprising:
a dummy pattern positioned on the first insulating layer and surrounding a bottom surface of the cavity along a sidewall of the cavity.

7. The printed circuit board of claim 6,
wherein a first portion of the dummy pattern is positioned below the sidewall of the cavity.

8. The printed circuit board of claim 7,
wherein a second portion of the dummy pattern is exposed by the cavity.

9. The printed circuit board of claim 8, further comprising:
a connecting portion positioned in the cavity and positioned on the first insulating layer,
wherein the dummy pattern and the connecting portion are positioned on the same layer and include the same material.

10. The printed circuit board of claim 9,
wherein a thickness of the dummy pattern is substantially the same as a thickness of the connecting portion.

11. The printed circuit board of claim 5,
wherein the second insulating layer includes a photosensitive insulating layer.

12. The printed circuit board of claim 1, further comprising:
a pad layer positioned on the insulating layer,
wherein the solder resist layer has a first opening that exposes the pad layer, and
wherein a thickness of the blocking pattern is substantially the same as a thickness of the pad layer.

13. The printed circuit board of claim 12,
wherein the blocking pattern and the pad layer are positioned on the same layer and include the same material.

14. The printed circuit board of claim 12,
wherein the insulating layer includes a first insulating layer and a second insulating layer positioned on the first insulating layer,
wherein the wiring layer includes a first wiring layer embedded in the first insulating layer and a second wiring layer embedded in the second insulating layer, and
wherein the cavity penetrates the second insulating layer and exposes a portion of the first insulating layer.

15. The printed circuit board of claim 14, further comprising:
a dummy pattern positioned between the first insulating layer and the second insulating layer and surrounding a bottom surface of the cavity along a sidewall of the cavity.

16. The printed circuit board of claim 15,
wherein a first portion of the dummy pattern is positioned below the sidewall of the cavity.

17. The printed circuit board of claim 16,
wherein a second portion of the dummy pattern is exposed by the cavity.

18. The printed circuit board of claim 17, further comprising:
a connecting portion positioned in the cavity and positioned on the first insulating layer; and
wherein the dummy pattern and the connecting portion are positioned on the same layer and include the same material as each other.

19. The printed circuit board of claim 18,
wherein a thickness of the dummy pattern is substantially the same as a thickness of the connecting portion.

20. The printed circuit board of claim 14,
wherein the second insulating layer includes a photosensitive insulating layer.
